(19) United States
(12) Patent Application Publication
(10) Pub. No.: US 2011/0067998 A1
(43) Pub. Date: Mar. 24, 2011

(54) METHOD OF MAKING AN ELECTRICALLY CONDUCTIVE CADMIUM SULFIDE SPUTTERING TARGET FOR PHOTOVOLTAIC MANUFACTURING

(75) Inventor: Stephen Barry, San Jose, CA (US)

(73) Assignee: MIASOLE, Santa Clara, CA (US)

(21) Appl. No.: 12/563,138

(22) Filed: Sep. 20, 2009

(51) Int. Cl. C23C 14/34; B22F 3/02; B22F 3/15; B22F 3/10; B29C 67/24

(52) U.S. Cl. 204/192.29; 204/192.25; 204/298.13; 419/66; 419/68; 419/10; 264/122

(57) ABSTRACT

An electrically conductive cadmium sulfide sputtering target, the method of making the same, and the method of manufacturing a photovoltaic cell using the same.

### FIELD OF THE INVENTION

The present invention relates generally to the field of photovoltaic modules, and specifically to forming thin-film photovoltaic cells by sputter depositing a cadmium sulfide layer using an electrically conductive cadmium sulfide sputtering target.

### BACKGROUND OF THE INVENTION

Deposition of thin-film layers in the manufacturing of thin-film photovoltaic modules may be achieved through several coating processes including chemical bath deposition, vapor deposition and sputtering, to name a few. Sputtering deposition is considered to be an efficient and effective method of depositing thin-films for use in photovoltaic modules.

### SUMMARY OF SPECIFIC EMBODIMENTS

One embodiment of the present invention provides a method of manufacturing a photovoltaic cell including providing an electrically conductive cadmium sulfide sputtering target, depositing a first electrode over a substrate, depositing at least one p-type semiconductor absorber layer over the first electrode, depositing an n-type semiconductor layer over the p-type semiconductor layer, wherein the n-type semiconductor layer comprises cadmium sulfide and wherein the step of depositing the n-type layer comprises sputtering from the electrically conductive cadmium sulfide sputtering target, and depositing a second electrode over the n-type semiconductor layer. The step of providing an electrically conductive cadmium sulfide target may comprise combining cadmium sulfide material and at least one dopant material forming a homogenous mixture and consolidating the mixture into a sputtering target, the homogeneous mixture having a dopant material content of 100 ppm to 2000 ppm.

Another embodiment of the invention provides a method of forming an electrically conductive cadmium sulfide sputtering target comprising providing cadmium sulfide material and at least one dopant material and combining the cadmium sulfide material and the at least one dopant material into a homogenous mixture and consolidating the mixture to form the electrically conductive cadmium sulfide sputtering target, the homogeneous mixture having a dopant material content of 100 ppm to 2000 ppm.

Another embodiment of the invention provides an electrically conductive cadmium sulfide sputtering target comprising cadmium sulfide and at least one dopant.

### BRIEF DESCRIPTION OF THE DRAWINGS

FIG. 1 is a schematic side cross-sectional view of a thin-film photovoltaic cell according to one embodiment of the invention.

FIG. 2 is a schematic diagram of a modular sputtering apparatus that can be used to manufacture the photovoltaic cell depicted in FIG. 1.

### DETAILED DESCRIPTION OF PREFERRED EMBODIMENTS

Several types of sputtering processes may be used to deposit thin-films for use in photovoltaic modules, including but not limited to DC, AC and RF sputtering. DC sputtering, DC pulse sputtering, and AC sputtering techniques are commonly used when the target comprises an electrically conductive substance. Conversely, RF sputtering techniques are commonly used when a sputtering target is not electrically conductive. RF sputtering has significant disadvantages compared to DC sputtering, DC pulse sputtering, and AC sputtering in that it exhibits low deposition rates, requires expensive power supplies, and requires costly RF isolation hardware between adjacent sputtering sources to prevent non-uniform deposition on substrates.”

Cadmium sulfide can be used as an n-type semiconductor layer in photovoltaic modules. However, cadmium sulfide is an electrically non-conductive substance that cannot be DC sputtered, DC pulse sputtered, or AC sputtered when presented in its pure form. While RF sputtering can be used to deposit cadmium sulfide thin films, RF sputtering suffers from the many disadvantages described above. Additionally, while cadmium sulfide may be deposited by use of chemical bath deposition, cadmium sulfide is a toxic heavy metal and it is not desirable to create large amounts of cadmium waste through the use of large scale cadmium deposition baths required for production.

It would be advantageous to provide a method of depositing cadmium sulfide through DC sputtering, DC pulse sputtering, or AC sputtering to facilitate uniform deposition at high deposition rates without generating large amounts of hazardous waste.

One embodiment of the present invention provides a method of manufacturing a photovoltaic cell comprising providing an electrically conductive cadmium sulfide sputtering target, depositing a first electrode over a substrate, depositing at least one p-type semiconductor absorber layer over the first electrode, depositing an n-type semiconductor layer over the p-type semiconductor absorber layer, wherein n-type semiconductor layer includes cadmium sulfide, wherein the step of depositing the n-type semiconductor layer comprises sputtering from the electrically conductive cadmium sulfide target, and depositing a second electrode over the n-type semiconductor layer. The step of providing an electrically conductive cadmium sulfide target may comprise combining cadmium sulfide material and at least one dopant material forming a homogenous mixture and consolidating the mixture into a sputtering target, the homogeneous mixture having a dopant material content of 100 ppm to 4000 ppm, such as 300 ppm to 3000 ppm, or 500 ppm to 2000 ppm. For the purposes of the present invention, the term homogeneous mixture means a mixture that is uniform throughout.

Another embodiment of the present invention provides a method of forming an electrically conductive cadmium sulfide sputtering target comprising providing cadmium sulfide material, adding at least one dopant material, forming a homogenous mixture and consolidating the mixture into a sputtering target. The step of consolidating the mixture into a sputtering target may comprise employing processes including but not limited to uniaxial pressing, cold isostatic pressing (CIP), hot isostatic pressing (HIP), or sintering with or without a subsequent partial densification step. The step of providing cadmium sulfide material may comprise providing cadmium sulfide crystals or cadmium sulfide powder or a combination thereof.

If heat is used during consolidation of the target, the maximum temperature used during pressing may include up to the melting point of the dopant material. For example, in the case of antimony, the target assembly could be heated up to 630° C., the melting point of elemental antimony.

The dopant material may comprise a suitable electron donor or electron acceptor that is capable of rendering a cadmium sulfide target electrically conductive. The dopant materials may be independently selected from a group consisting of but not limited to arsenic, antimony, iron, aluminum, boron, or combinations thereof. The dopant materials may be used in their solid, elemental state.

The dopant material should occupy a ratio of the sputtering target sufficient to render the sputtering target electrically conductive, but the semiconductive properties of a deposited cadmium sulfide layer should not be diminished upon deposition. The electrically conductive cadmium sulfide sputtering target could have a resistivity value between 1.0×10⁶ ohm·cm and 1.59×10⁸ ohm·cm, such as between 1.0×10⁵ ohm·cm and 1.0×10⁻¹ ohm·cm. The dopant material could be used in a range of 100 ppm to 4000 ppm, such as 300 ppm to 3000 ppm, or 500 ppm to 2000 ppm. Reactive sputtering could be used to decrease the likelihood that the semiconductive properties of the deposited thin-film will be lost. For instance, sputtering could be conducted in an atmosphere containing both argon and oxygen to decrease the conductivity of the dopant upon deposition.

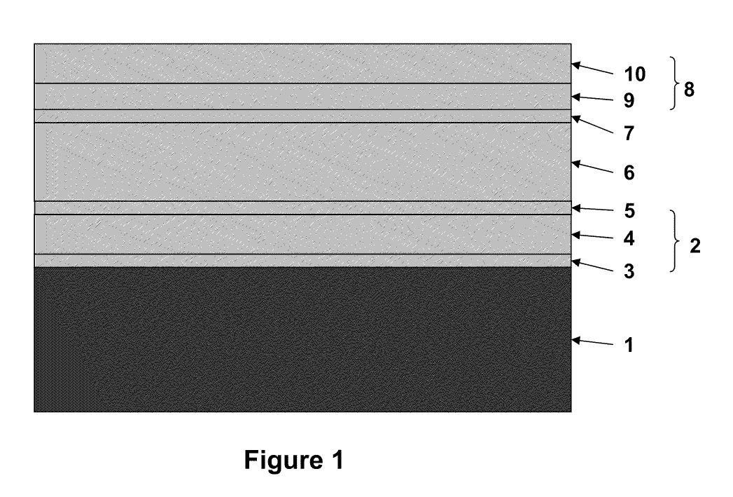

One embodiment of the present invention provides a photovoltaic cell having a structure illustrated in FIG. 1. The photovoltaic cell contains the substrate 1 and a first (lower) electrode 2. Optionally, the first electrode 2 of the photovoltaic cell may comprise one or more barrier layers 3 located under a transitional metal layer 4, and/or one or more adhesion layers 5 located over the transition metal layer 4. The optional barrier layer 3 and adhesion layer 5 may comprise any suitable materials. For example, they may be independently selected from a group consisting of Mo, W, Ta, V, Ti, Nb, Zr, Cr, TiN, ZrN, TaN, VN, V₂N or combinations thereof. In one embodiment, while the barrier layer 3 may be oxygen free, the transition metal layer 4 and/or the adhesion layer 5 may contain oxygen and/or be deposited at a higher pressure than the barrier layer 3 to achieve a lower density than the barrier layer 3. For example, transition metal layer 4 may optionally contain 5 to 40 atomic percent oxygen and adhesion layer 5 may optionally contain 1 to 10 atomic percent oxygen.

Alternatively, the optional one or more barrier layers 3 and/or one or more adhesion layers 5 may be omitted. When the optional one or more adhesion layers 5 are omitted, the at least one p-type semiconductor absorber layer 6 is deposited over the transition metal layer 4.

In preferred embodiments, the p-type semiconductor absorber layer 6 may comprise a CIS based alloy material or a cadmium telluride layer. The CIS based alloy material may be selected from copper indium selenide, copper indium gallium selenide, copper indium aluminum selenide, or combinations thereof. The steps of depositing the at least one p-type semiconductor absorber layer may comprise reactively sputtering the semiconductor absorber layer from at least one electrically conductive targets.

An n-type semiconductor layer 7 may then be deposited over the p-type semiconductor absorber layer 6, wherein the n-type semiconductor layer comprises cadmium sulfide. The step of depositing the n-type semiconductor layer 7 over the p-type semiconductor absorber layer 6 may comprise DC sputtering, DC pulse sputtering, or AC sputtering the n-type semiconductor layer from an electrically conductive target in an atmosphere that comprises argon gas. Alternatively, the step of depositing the n-type semiconductor layer 7 over the p-type semiconductor absorber layer 6 may comprise reactive DC sputtering, reactive DC pulse sputtering, or reactive AC sputtering the n-type semiconductor layer from an electrically conductive target in an atmosphere that comprises argon and oxygen-containing gas. The sputtering atmosphere may contain 1 to 50 volume percent (also referred to as molar percent) of oxygen-containing gas, such as 5 to 10 volume percent. Examples of oxygen-containing gas may include but are not limited to O₂ or H₂O. The target may have a hollow cylinder shape for being mounted in a rotating target DC or AC sputtering system or the target may be a planar target.

A second electrode 8, also referred to as a transparent top electrode, is further deposited over the n-type semiconductor layer 7. The transparent top electrode 8 may comprise multiple transparent conductive layers, for example, but not limited to, one or more of an Indium Tin Oxide (ITO), Zinc Oxide (ZnO) or Aluminum Zinc Oxide (AZO) layers 10 located over an optional resistive Aluminum Zinc Oxide (RAZO) layer 9. Of course, the transparent top electrode 8 may comprise any other suitable materials, for example, doped ZnO or SnO.

Optionally, one or more antireflection (AR) films (not shown) may be deposited over the transparent top electrode 8, to optimize the light absorption in the cell, and/or current collection grid lines may be deposited over the top conducting oxide.

Alternatively, the photovoltaic cell may be formed in reverse order. In this configuration, a transparent electrode is deposited over a substrate, followed by depositing an n-type semiconductor layer over the transparent electrode wherein the n-type semiconductor layer comprises cadmium sulfide, depositing at least one p-type semiconductor absorber layer over the n-type semiconductor layer, and depositing a top electrode comprising a transition metal layer over the at least one p-type semiconductor absorber layer. The substrate may be a transparent substrate (e.g. glass) or opaque (e.g. metal). If the substrate used is opaque, then the initial substrate may be delaminated after the steps of depositing the stack of the above described layers, and then binding a glass or other transparent substrate to the transparent electrode of the stack.

More preferably, the steps of depositing the first electrode 2, depositing at least one p-type semiconductor absorber layer 6, depositing the n-type semiconductor layer 7, and depositing the second electrode 8 comprise sputtering the first electrode layer 2, the p-type semiconductor absorber layer 6, the n-type semiconductor layer 7 and one or more conductive films of the second electrode 8 over the substrate 1 (preferably a web substrate in this embodiment) in corresponding process modules of a series of independently isolated, connected process modules without breaking vacuum, while passing the web substrate 1 from an input module to an output module through the series of independently isolated, connected process modules such that the web substrate continuously extends from the input module to the output module while passing though the series of the independently isolated, connected process modules. Each of the process modules may include one or more sputtering targets for sputtering material over the web substrate 1.

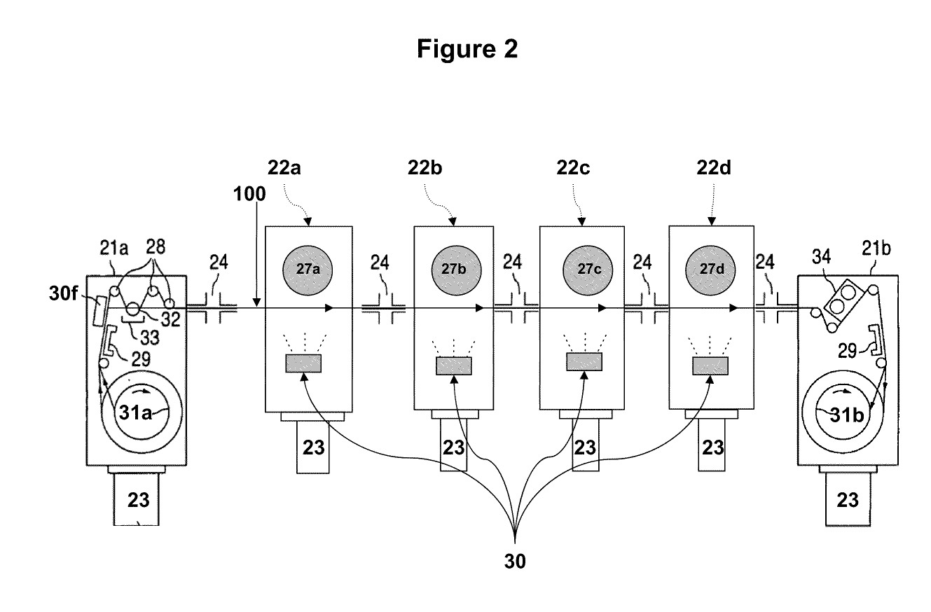

For example, a modular sputtering apparatus for making the photovoltaic cell, as illustrated in FIG. 2 (top view), may be used for depositing the layers. The apparatus is equipped with an input, or load, module 21a and a symmetrical output, or unload, module 21b. Between the input and output modules are process modules 22a, 22b, 22c, and 22d. The number of process modules 22 may be varied to match the requirements of the device that is being produced. Each module has a pumping device 23, such as a vacuum pump, for example a high throughput turbomolecular pump, to provide the required vacuum and to handle the flow of process gases during the sputtering operation. Each module may have a number of pumps placed at other locations selected to provide optimum pumping of process gases. The modules are connected together at slit valves 14, which contain very narrow low conductance isolation slots to prevent process gases from mixing between modules. These slots may be separately pumped if required to increase the isolation even further. Other module connectors 14 may also be used. Alternatively, a single large chamber may be internally segregated to effectively provide the module regions, if desired. U.S. Published Application No. 2005/0109392 A1 (“Hollars”), filed on Oct. 25, 2004, discloses a vacuum sputtering apparatus having connected modules, and is incorporated herein by reference in its entirety.

The web substrate 1 is moved through the machine by rollers 28, or other devices. Additional guide rollers may be used. Rollers shown in FIG. 2 are schematic and non-limiting examples. Some rollers may be bowed to spread the web, some may move to provide web steering, some may provide web tension feedback to servo controllers, and others may be mere idlers to run the web in desired positions. The input spool 31a and optional output spool 31b thus are actively driven and controlled by feedback signals to keep the web in constant tension throughout the machine. In addition, the input and output modules may each contain a web splicing region or device 29 where the web 1 can be cut and spliced to a leader or trailer section to facilitate loading and unloading of the roll. In some embodiments, the web 1, instead of being rolled up onto output spool 31b, may be sliced into photovoltaic modules by the web splicing device 29 in the output module 21b. In these embodiments, the output spool 31b may be omitted. As a non-limiting example, some of the devices/steps may be omitted or replaced by any other suitable devices/steps. For example, bowed rollers and/or steering rollers may be omitted in some embodiments.

Heater arrays 30 are placed in locations where necessary to provide web heating depending upon process requirements. These heaters 30 may be a matrix of high temperature quartz lamps or resistive heating elements laid out across the width of the web. Infrared sensors or thermocouples may provide a feedback signal to servo the heating element power and provide uniform heating across the web. In one embodiment, as shown in FIG. 2, the heaters are placed on one side of the web 1, and sputtering targets 27 are placed on the other side of the web 1. Sputtering targets 27 may be mounted on dual cylindrical rotary magnetron(s), or planar magnetron(s) sputtering sources, or RF sputtering sources.

After being pre-cleaned, the web substrate 1 may first pass by heater array 30f in module 21a, which provides at least enough heat to remove surface absorbed water. Subsequently, the web can pass over roller 32, which can be a special roller configured as a cylindrical rotary magnetron. This allows the surface of electrically conducting (metallic) webs to be continuously cleaned by DC, AC, or RF sputtering as it passes around the roller/magnetron. The sputtered web material is caught on shield 33 which is periodically changed. Preferably, another roller/magnetron may be added (not shown) to clean the back surface of the web 1. Direct sputter cleaning of a web 1 will cause the same electrical bias to be present on the web throughout the machine, which, depending on the particular process involved, might be undesirable in other sections of the machine. The biasing can be avoided by sputter cleaning with linear ion guns instead of magnetrons, or the cleaning could be accomplished in a separate smaller machine prior to loading into this large roll coater. Also, a corona glow discharge treatment could be performed at this position without introducing an electrical bias.

Next, the web 1 passes into the process module 22a though valve 24. Following the direction of the imagery arrows along the web 1, the full stack of layers may be deposited in one continuous process. The first electrode 2, may be sputtered in the process module 22a over the web 1, as illustrates in FIG. 2. Optionally, the process module 22a may include more than one target, the target comprising an alkali-containing transition metal target 27a.

The web 1 then passes into the next process module, 22b, for deposition of the at least one p-type semiconductor absorber layer 6. In a preferred embodiment shown in FIG. 2, the step of depositing the at least one p-type semiconductor absorber layer 6 includes reactively sputtering the semiconductor absorber layer from at least one conductive target 19b in a sputtering atmosphere that comprises argon gas.

Optionally, one or more process modules (not shown) may be added between the process modules 21a and 22a to sputter a back side protective layer over the back side of the substrate 1 before the electrode 2 is deposited on the front side of the substrate. U.S. application Ser. No. 12/379,428 (Attorney Docket No. 075122/0139) titled “Protective Layer for Large-Scale Production of Thin-Film Photovoltaic Cells” and filed on Feb. 20, 2009, which is hereby incorporated by reference, describes such deposition process. Further, one or more barrier layers 3 may be sputtered over the front side of the substrate 1 in the process module(s) added between the process modules 21a and 22a. Similarly, one or more process modules (not shown) may be added between the process modules 22a and 22b, to sputter one or more adhesion layers 5 between the transition metal layer 4 and the CIGS layer 6.

The web 1 may then pass into the process modules 22c and 22d, for depositing the n-type semiconductor layer 7, and the transparent top electrode 8, respectively. DC or AC magnetrons may be used for deposition of the cadmium sulfide n-type semiconductor layer 7 from the electrically conductive cadmium sulfide target 27c. Any suitable type of sputtering sources may be used, for example, rotating AC magnetrons, RF magnetrons, or planar magnetrons for depositing the transparent top electrode 8 from the transparent top electrode sputtering target 27d. Extra magnetron stations (not shown) or extra process modules (not shown) could be added for sputtering the optional one or more AR layers.

Finally, the web 1 passes into output module 21b, where it is either wound onto the take up spool 31b, or sliced into photovoltaic cells using cutting apparatus 29. While sputtering was described as the preferred method for depositing all layers onto the substrate, some layers may be deposited by MBE, CVD, evaporation, plating, etc., while, preferably, the CIS based alloy is reactively sputtered.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A method of manufacturing a photovoltaic cell comprising:
providing an electrically conductive cadmium sulfide target, wherein the cadmium sulfide target is formed by combining cadmium sulfide material and at least one dopant material into a homogenous mixture and consolidating the mixture into the electrically conductive cadmium sulfide sputtering target, the homogeneous mixture having a dopant material content of 100 ppm to 4000 ppm;
depositing a first electrode over a substrate;
depositing at least one p-type semiconductor absorber layer over the first electrode;
depositing an n-type semiconductor layer over the p-type semiconductor absorber layer, wherein the step of depositing the n-type semiconductor layer comprises sputtering from the electrically conductive cadmium sulfide-containing target; and
depositing a second electrode over the n-type semiconductor layer.

2. The method as recited in claim 1, wherein the at least one dopant material is selected from a group consisting of As, Sb, Fe, Al, and B.

3. The method as recited in claim 2, wherein the at least one dopant material comprises B.

4. The method as recited in claim 2, wherein the at least one dopant material is in its solid elemental form.

5. The method as recited in claim 1, wherein the cadmium sulfide material is in the form of cadmium sulfide crystals.

6. The method as recited in claim 1, wherein the step of consolidating the target comprises a process selected from a group consisting of uniaxial pressing, cold isostatic pressing, hot isostatic pressing, and sintering.

7. The method as recited in claim 6, wherein the step of consolidating the target comprises the process hot isostatic pressing.

8. The method as recited in claim 1, wherein the step of consolidating the mixture into the electrically conductive cadmium sulfide sputtering target comprises the homogeneous mixture having a dopant material content of 300 ppm to 3000 ppm

9. The method as recited in claim 1, wherein the step of consolidating the mixture into the electrically conductive cadmium sulfide sputtering target comprises the homogeneous mixture having a dopant material content of 500 ppm to 2000 ppm

10. The method as recited in claim 1, wherein sputtering from the electrically conductive cadmium sulfide-containing target comprises pulsed or non-pulsed DC sputtering or AC sputtering from the conductive cadmium sulfide-containing target.

11. The method as recited in claim 1, wherein the substrate comprises a web substrate, the web substrate being selected from a metal web substrate, a polymer web substrate, or a polymer coated metal web substrate.

12. A method of forming an electrically conductive cadmium sulfide sputtering target, comprising:
providing cadmium sulfide material;
providing at least one dopant material; and
combining the cadmium sulfide material and the at least one dopant material into a homogenous mixture and consolidating the mixture into the electrically conductive cadmium sulfide sputtering target, the homogeneous mixture having a dopant material content of 100 ppm to 4000 ppm.

13. The method as recited in claim 12, wherein the at least one dopant material is selected from a group consisting of As, Sb, Fe, Al, and B.

14. The method as recited in claim 13, wherein the at least one dopant material comprises B.

15. The method as recited in claim 13, wherein the at least one dopant material is in its solid elemental form.

16. The method as recited in claim 12, wherein the cadmium sulfide material is in the form of cadmium sulfide crystals.

17. The method as recited in claim 12, wherein the step of consolidating the mixture to form the electrically conductive cadmium sulfide sputtering target comprises a process selected from a group consisting of uniaxial pressing, cold isostatic pressing, hot isostatic pressing, and sintering.

18. The method as recited in claim 17, wherein the step of consolidating the mixture to form the electrically conductive cadmium sulfide sputtering target comprises the process hot isostatic pressing.

19. The method as recited in claim 12, wherein the at least one dopant material is present in the target at 300 to 3000 ppm.

20. The method as recited in claim 12, wherein the at least one dopant material is present in the target at 500 to 2000 ppm.

21. The method as recited in claim 12, wherein the electrically conductive cadmium sulfide target has a resistivity between 1.0×10⁶ ohm·cm and 1.59×10⁻⁸ ohm·cm.

22. The method as recited in claim 12, wherein the electrically conductive cadmium sulfide target has a resistivity between 1.0×10⁵ ohm·cm and 1.0×10⁻¹ ohm·cm.

23. A method of manufacturing a photovoltaic cell comprising:
Providing an electrically conductive cadmium sulfide target, wherein the electrically conductive cadmium sulfide target is formed by combining cadmium sulfide and at least one dopant material into a homogenous mixture and consolidating the mixture into the electrically conductive cadmium sulfide sputtering target, the homogeneous mixture having a dopant material content of 100 ppm to 4000 ppm;
depositing a transparent electrode over a substrate;
depositing an n-type semiconductor layer over the transparent electrode, wherein the step of depositing the n-type semiconductor layer comprises sputtering from the electrically conductive cadmium sulfide target;
depositing at lest one p-type semiconductor absorber layer over the n-type semiconductor layer; and
depositing a top electrode over the at least one p-type semiconductor absorber layer.

24. The method as recited in claim 23, wherein the at least one dopant material is selected from a group consisting of As, Sb, Fe, Al, and B.

25. The method as recited in claim 24, wherein the at least one dopant material comprises B.

26. The method as recited in claim 24, wherein the at least one dopant material is in its solid elemental form.

27. The method as recited in claim 23, wherein the cadmium sulfide material is in the form of cadmium sulfide crystals.

28. The method as recited in claim 23, wherein the step of consolidating the mixture to form the electrically conductive cadmium sulfide sputtering target comprises a process selected from a group consisting of uniaxial pressing, cold isostatic pressing, hot isostatic pressing, and sintering.

29. The method as recited in claim 28, wherein the step of consolidating the mixture to form the electrically conductive cadmium sulfide sputtering target comprises the process hot isostatic pressing.

30. The method as recited in claim 23, wherein the step of consolidating the mixture into the electrically conductive cadmium sulfide sputtering target comprises the homogeneous mixture having a dopant material content of 300 ppm to 3000 ppm

31. The method as recited in claim 23, wherein the step of consolidating the mixture into the electrically conductive cadmium sulfide sputtering target comprises the homogeneous mixture having a dopant material content of 500 ppm to 2000 ppm

32. The method as recited in claim 23, wherein sputtering from the electrically conductive cadmium sulfide-containing target comprises pulsed or non-pulsed DC sputtering or AC sputtering from the conductive cadmium sulfide-containing target.

33. The method as recited in claim 23, wherein the substrate comprises a web substrate, the web substrate being selected from a metal web substrate, a polymer web substrate, or a polymer coated metal web substrate.

34. A sputtering target configured for DC or AC sputtering, comprising doped cadmium sulfide having a dopant material content of 100 ppm to 4000 ppm.

35. The sputtering target of claim 34, wherein the sputtering target is mounted in a pulsed or non-pulsed DC sputtering system; and
the doped cadmium sulfide comprising a dopant material content of 500 ppm to 2000 ppm.
